(19) United States
(12) Patent Application Publication
(10) Pub. No.: US 2023/0155339 A1
(43) Pub. Date: May 18, 2023

(54) DOUBLE-PULSE LASER SYSTEM

(71) Applicant: Thermo Fisher Scientific (Ecublens) SARL, Ecublens (CH)

(72) Inventor: Patrick Lancuba, Madison, WI (US)

(21) Appl. No.: 17/906,379

(22) PCT Filed: Mar. 18, 2021
(86) PCT No.: PCT/EP2021/056946

§ 371 Date: Sep. 15, 2022

(30) Foreign Application Priority Data
Mar. 18, 2020 (GB) 2003948.3

(51) Int. Cl. H01S 3/00; H01S 3/102; H01S 5/00

(52) U.S. Cl. CPC H01S 3/0071; H01S 3/102; H01S 5/005

(57) ABSTRACT

A double-pulse laser system for generating first and second laser pulses, comprising a multipass cell (300) arranged to delay the second laser pulse with respect to the first laser pulse, wherein the multipass cell comprises first (305A, 305B) and second (307) reflector arrangements defining an optical cavity (315) in which the delayed second laser pulse is reflected back and forth multiple times between the first (305A, 305B) and second (307) reflector arrangements to provide a temporal delay between the first and second pulses of 1 ns or greater.

### FIELD

The present disclosure relates generally to a double-pulse laser system and to the use of such a system in various fields, including in optics and atomic emission spectroscopy.

### BACKGROUND

Optical pulses are used throughout optics and in scientific analysis. Optical pulses are characterised by a rapid, transient change in the amplitude of a signal from a baseline value to a higher or lower value, followed by a rapid return to the baseline value. Optical pulses can be pulses of any type of electromagnetic radiation including, for example, visible light or invisible electromagnetic radiation.

When multiple (e.g. two or more) laser pulses are required in quick succession, they are often generated using complex and expensive electronics or by using two different pulsed lasers.

Two pulses can be provided by using a single-pulsed laser with modified electronics to control the Q-switch and emit two pulses with a predetermined time delay. In this case, only one laser is necessary, and the two pulses may be emitted collinearly. However, there are high costs associated with the modification of the electronics and there is little flexibility in choosing different time delays (with delays typically being on the order of ˜100 μs). In particular, the duration of the delay strongly affects the energies of the pulses and it can be difficult to provide two pulses of comparable energies.

Alternatively, two pulses can be provided by causing the beams of two different pulsed lasers to travel along a common path, where an external trigger causes each laser to emit a pulse with a time delay between the first and second pulses. This requires two lasers, which leads to a doubling in the cost of the system and an increase in the size of the system. Moreover, there is a requirement for precise adjustment of the spatial superimposition of the two pulses.

A scenario in which laser pulses are utilised is laser-induced breakdown spectroscopy (LIBS). LIBS has been used for chemical analytical purposes since the 1970s. However, a transfer to quantitative analysis applications was prevented because of insufficient performance compared with other optical emission spectrometric (OES) methods, such as spark-OES or inductively-coupled-plasma-OES.

In LIBS, a laser pulse is used to excite a sample. Crucial factors in LIBS are the laser parameters and the interaction of the laser with the material to be analysed. For quantitative analysis, the line emission strength depends on: 1) the amount of material ablated and 2) the temperature of the plasma in the plume. Single pulses, i.e. one laser pulse per pump pulse, are the conventional approach to ablate and vaporise material and to induce the plasma. Nevertheless, if single pulses are used, then ablation and plasma excitation cannot be optimised separately. As the plasma expands from the surface, it begins to absorb the tail of the incoming radiation, increasing the plume temperature, but limiting the amount of light reaching the sample surface and thus limiting the total amount of material ablated. Shorter pulses can be used to ablate more matter at the expenses of the plume temperature and, conversely, longer pulses can be used to increase the plume temperature, but result in line emission saturation arising from the plasma absorption. Similarly, higher single pulse energies do not lead to stronger emission lines precisely because of this saturation effect.

To optimise line emission strengths, double-pulse LIBS systems have been proposed. These utilise a train of two laser pulses, which are separated in time by several 10s of nanoseconds up to several microseconds. In a collinear geometry setup, i.e. when the two pulses are directed toward the surface following the same optical path, the first pulse reaches the sample and creates a corresponding first, expanding plasma plume. As this expands, the pressure of the plume decreases and so does its temperature. After a predefined time delay, the second pulse reaches the sample through the plasma plume generated by the first pulse. As the plasma plume density created by the first pulse is strongly decreased by supersonic expansion, this second pulse is partially transmitted and impacts the sample surface, where it generates a new plasma plume. In addition, the energy component absorbed by the first plasma plume causes its temperature to increase. The overall effect is increased material ablation and temperature, which leads to stronger line emissions. Comparative studies of Single and Double pulse systems show a line emission strength increase of typically 10-50 times and up to 100 times for certain elements.

To date, double-pulse LIBS systems have typically employed complex Q-switching circuitry or the use of multiple lasers, and so such double-pulse LIBS systems suffer from the previously-noted drawbacks of these approaches. As both approaches cause difficulties for industrial implementations in terms of cost and complexity, existing double-pulse LIBS systems are expensive and complex.

It is an object of this disclosure to address these and other problems with prior art LIBS systems and with prior art double-pulse laser systems in general.

### SUMMARY

Against this background and in accordance with a first aspect, there is provided a double-pulse laser system according to claim 1. A double-pulse laser-induced breakdown spectrometer according to claim 35 is also provided.

The present disclosure relates to the use of a multipass cell in a double-pulse laser system to provide a delay between first and second laser pulses. By directing one pulse into a multipass cell, that pulse may be delayed with respect to another pulse that does not enter the cell, by virtue of the multipass cell providing a longer optical path length for the pulse in the cell than the pulse that does not enter the cell. The use of a multipass cell for this purpose provides a way of delaying a laser pulse without requiring the use of complex electronics.

The pulses may be generated from a single pulse, for instance by splitting a single pulse. This means that a single laser can be used to provide two (e.g. only two, or in some cases at least two) coherent pulses, avoiding the need to use two lasers. Moreover, the disclosure provides a means for dividing a pulse into two pulses. By providing an aperture in a reflective surface and directing a pulse at the edge of the aperture, a portion of a pulse can be caused to pass through the aperture and a portion of the pulse can be reflected, thereby splitting the pulse. This is an efficient and reliable mechanism for splitting laser pulses and can be integrated easily with a multipass cell (e.g. by attaching the reflective surface having an aperture to the exterior of the cell). Arrangements of conventional beamsplitters can be used additionally and/or alternatively.

In preferred embodiments, in which two pulses are generated from a single pulse, the energy of the single pulse can be divided substantially equally between the two pulses. For instance, in general terms, each of first and second pulses can have equal energy (e.g. 50% of the energy of the energy of the original single pulse). This can be achieved using the arrangements described herein, including using conventional beamsplitters arranged as described herein, or using the mechanical beam splitting techniques (e.g. using a reflective surface having an aperture) described herein.

As the first and second laser pulses of the present disclosure can be generated from a single laser pulse, the first and second laser pulses preferably have the same frequency. Thus, pulses with substantially equal energy, frequency, intensity and/or size may be provided. Additionally, using the splitting techniques described herein, the splitting of a laser pulse can occur independently of the frequency of the laser pulse. Moreover, in some systems of the present disclosure, splitting can occur independently of the polarisation of the laser pulse.

Some specific examples of multipass cells described in this disclosure have particular advantages for use in double-pulse laser systems, as they are highly stable and relatively inexpensive to manufacture. For instance, such cells can provide an optical path length of up to or greater than 50 or 100 metres. The disclosure provides an optical structure that can be fabricated using inexpensive, commercially available components and which exhibits remarkable mechanical tolerances that make it suitable to withstand vibrations and simplify mechanical alignment in industrial implementations.

Some of the multipass cells of the disclosure are based on the combination of two prism mirrors and a concave (e.g. spherical) mirror, which respectively serve as two ends of a multipass cell. The prisms define a first end and the concave mirror defines a second opposing end. Light can enter through one end of the cell (typically between the prisms) and bounce repeatedly between the first and second ends of the cell. The optical properties of the combination of two prisms leads to enhanced stability compared to existing multipass cells. For instance, because the prisms are arranged to have perpendicular surfaces, light that is reflected by the concave mirror towards the prisms is at least partially retroreflected by the prisms. Therefore, the spreading of light as it repeatedly traverses the cell can be reduced. Although in principle, divergence of light could occur due to slight misalignment of the optical system, imperfections in the surface of the prisms and/or imperfections in the waveform of the light that enters the cell, in the presently described multipass cells, the partially retroreflective end of the cell is less sensitive to these imperfections and so their effects are reduced.

The advantage of improved stability due to reduced spreading of light can also be achieved using three mutually perpendicular reflective surfaces (e.g. a corner reflector). The use of a partially (or fully) retroreflective end of the cell is particularly advantageous in combination with a concave (e.g. a focusing) reflector at the other end of the cell.

The multipass cells of the disclosure provide additional benefits. For instance, whilst perpendicular reflective surfaces can be provided using, for example, two mirrors, the combination of two prisms (and especially two prims whose cross sections are right-angled isosceles triangles) is particularly advantageous. Two right-angled isosceles triangular prisms can be positioned side-by side (resting on the face defined by the hypotenuse of the cross section, with the axes of the prisms parallel) such that they define a pair of perpendicular surfaces. Moreover, by positioning the prisms with a small slit between their edges (the edges that are parallel with the axes of the prisms), an aperture for allowing light to pass between the prisms can easily be provided. Triangular prisms are widely available optical components that are easy to arrange precisely (e.g. using a mounting structure) to provide the above-noted advantages and which provide a larger surface area for mounting within an optical arrangement, improving stability of the reflective surface. Therefore, prisms provide an efficient and reliable means for manufacturing a pair of perpendicular reflective surfaces.

The enhanced stability provided by the reflector arrangements of the disclosure allow the cells to provide extremely long optical path lengths (and hence also long durations of time during which light is within the cell) for any given separation between the reflectors. For instance, the separation between the ends of the cell can be adjusted and the angle at which light enters the cell can be adjusted. By changing these properties of the cell's geometry, the total path traversed by light within the cell can be adjusted from less than 1 m up to tens of metres or even greater than 100 m. This can provide relatively long path lengths for providing temporal delays between pulses in double-pulse laser systems. In general terms, greater separations between the ends of the cell lead to greater path lengths and increased path lengths can also be achieved by increasing the angle at which the light enters the cell (i.e. by entering the light at greater angle from the longitudinal axis of the cell). The described multipass cells are particularly tolerant to receipt of light at an angle (compared to prior art multipass cells, used in other fields) and so are particularly beneficial when integrated into a double-pulse laser system.

The double-pulse systems of the disclosure are particularly advantageous in the context of double-pulse laser induced breakdown spectroscopy, in which first and second pulses impact a sample and cause the sample to emit light. It is advantageous to provide relatively long temporal delays between pulses, without the need for complex electronics or multiple lasers, by using new combinations of widely-available optical components such as prisms and mirrors.

### LISTING OF FIGURES

Embodiments of the disclosure will now be described, by way of example only, with reference to the accompanying drawings in which:

FIG. 1 shows schematically a double-pulse laser system;

FIG. 2 shows schematically a double-pulse laser system comprising an optical arrangement for splitting light;

FIGS. 3A to 3D show schematically a multipass cell;

FIGS. 4A to 4C show stability analysis of the multipass cell;

FIG. 5 shows a standing mode of the multipass cell in an aligned state;

FIG. 6 shows standing modes of the multipass cell when subjected to misalignments;

FIG. 7 shows schematically a multipass cell;

FIG. 8 shows schematically an alternative first reflector arrangement for the multipass cells of FIGS. 3A to 3D and 7;

FIGS. 9A and 9B shows schematically mounting structures for the multipass cells described herein;

FIG. 10 shows the principle of splitting light;

FIGS. 11A to 11D shows schematically a double-pulse laser system utilising the multipass cells described herein;

FIGS. 12A and 12B shows a comparison of different types of mechanical beam splitting; and

FIG. 13 shows schematically a double-pulse laser-induced breakdown spectrometer utilising the multipass cells described herein.

### DETAILED DESCRIPTION

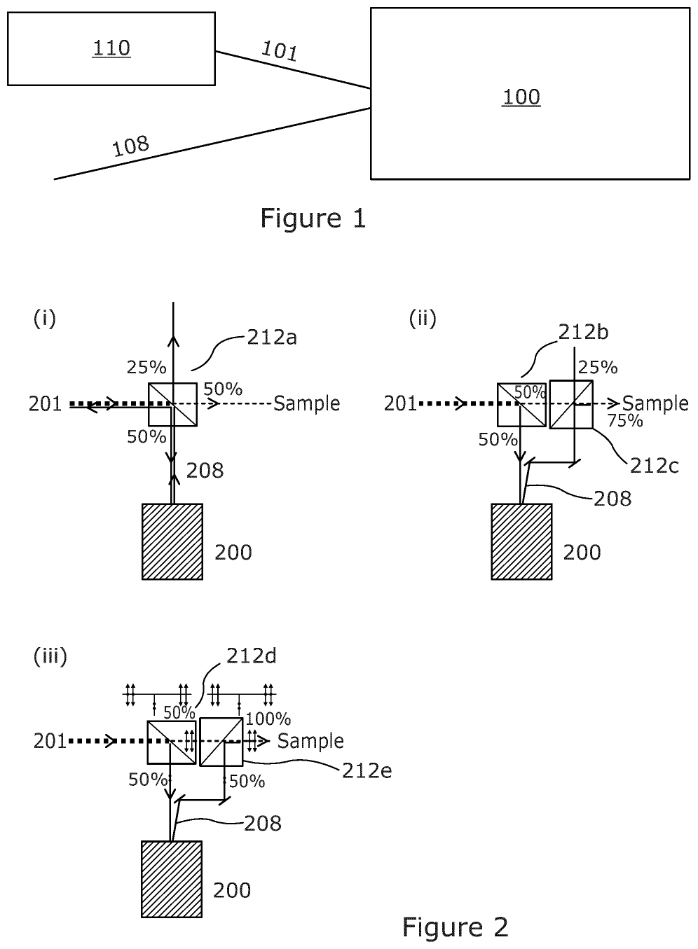

In FIG. 1, there is shown a generalised double-pulse laser system for generating first and second laser pulses. The system comprises a multipass cell 100 arranged to delay the second laser pulse with respect to the first laser pulse. The laser system additionally comprises a laser 110 for providing a single laser pulse, which is directed towards the multipass cell 100 along the direction 101. The multipass cell 100 receives the single laser pulse and causes two pulses to travel in the direction 108 with a temporal separation. The use of a multipass cell for introducing a delay between the first and second laser pulses advantageously requires less space and costs less than systems that use a plurality of lasers for generating multiple laser pulses. Moreover, the use of the multipass cell to introduce the delay between laser pulses eliminates the need for complex electronics for controlling Q-switching. In FIG. 1, the multipass cell 100 may itself be capable of splitting a single laser pulse into first and second laser pulses, or optical splitting elements (which be positioned between the laser 110 and the cell 100, for example) may perform this function.

FIG. 2 shows examples of multipass cells 200 and optical arrangements 212 for dividing laser pulses. In FIGS. 2(i), (ii) and (iii), single laser pulses 201 are depicted incident upon optical arrangements 212, which comprise beamsplitters 212a-e, for guiding light into multipass cells 200 and towards a sample. FIG. 2(i) depicts an optical arrangement 212 that generates first and second laser pulses but which fails to direct both pulses towards a desired destination. FIGS. 2(ii) and 2(iii) depict optical arrangements 212 that successfully generate first and second laser pulses having a relative time delay. In FIG. 2(ii), 75% of the total energy incident in the single laser pulse is eventually directed to the sample. In FIG. 2(iii), 100% of the total energy incident in the single laser pulse is eventually directed to the sample.

The optical arrangements 212 of FIG. 2 utilise beamsplitters. Beamsplitters can be unpolarising (sometimes described as non-polarising) or polarising. Polarising beamsplitters split light into two beams of orthogonal polarisation states. In addition to beamsplitters, the optical arrangements 212 also comprise reflecting elements (e.g. mirrors) for directing pulses towards the appropriate beamsplitters. Types of beamsplitter include: half-silvered mirrors; pairs of triangular prisms adhered together; Wollaston prisms; and dichroic mirrored prism assemblies (which use dichroic optical coatings).

In FIG. 2(i), a single unpolarising beamsplitter 212a is depicted. If a laser pulse 201 passes through one non-polarising beamsplitter, as shown in FIG. 2(i), then 50% is transmitted (toward the sample) and 50% is reflected. In FIG. 2(i), this is shown as being at a 90° clockwise angle with respect to the propagation axis of the incoming pulse. The reflected part of the light passes into the multipass cell 200 and once the pulse exits the cell 200 along the direction of the exiting light 208, it is incident upon the same beamsplitter 212a again. There, 50% of this pulse (that is, 25% of the total initial pulse energy) will be reflected back towards the laser source along the direction of the incoming light 201 (which is dangerous due to potentially damaging the source) and 50% will pass straight through the beamsplitter 212a and will not reach the sample.

FIG. 2(ii) depicts an optical arrangement 212 comprising two unpolarising beamsplitters 212b and 212c. FIG. 2(ii) improves upon configuration (i) by adding a second beamsplitter 212c rotated by 180° with respect to the first beamsplitter 212b. The first beamsplitter 212a splits a single laser pulse into first and second laser pulses. The first laser pulse passes straight through to the second beamsplitter 212c, which the first laser pulse also passes straight through. The first laser pulse therefore travels in the direction of a sample. The second laser pulse (i.e. the delayed pulse) passes into the multipass cell 200, traverses the cell one or more times, and emerges along the direction of the exiting light 208, before being guided to the second beamsplitter 212c. 50% of the second laser pulse passes straight through the second beamsplitter 212c and 50% of the second laser pulse is directed towards the sample, in a collinear direction to the first laser pulse. In this way, back-reflection to the laser source is avoided and 75% of the original laser energy reaches the sample, with 25% of the original laser pulse energy being the second laser pulse having a temporal delay with respect to the first laser pulse. This is not an optimum scenario due to the loss of 25% of the laser energy.

FIG. 2(iii) depicts an optical arrangement 212 comprising two polarising beamsplitters 212d and 212e. The first beamsplitter 212e splits the pulse according to its polarisation. Therefore, if circularly polarised light hits the beamsplitter 212e, the horizontal and the vertical components are separated. Each component corresponds to 50% of the pulse energy as the original pulse is circularly polarised. Hence, 50% of the pulse is transmitted toward the sample and 50% is reflected to the multipass cell 200. To avoid the same scenario as in Figure (i), a second polarised beamsplitter 212e (rotated by 180° with respect to the first polarised beamsplitter 212d) causes the two pulses to be targeted toward the sample. The advantage of this scenario is that 100% of the incident laser light is conserved, leading to increased efficiency with respect to FIG. 2(ii).

Hence, in generalised terms, the present disclosure provides embodiments in which an optical arrangement is configured to direct the second laser pulse into the multipass cell (e.g. so as to delay the second pulse with respect to the first pulse). The optical arrangement is preferably configured to generate the first and second laser pulses from a single laser pulse (e.g. by splitting a single pulse into two). The optical arrangement may be configured to split one pulse into only two pulses. Such pulses may have substantially equal energy (i.e. 50% of the energy of the pulse used to generate the pulses). The disclosure provides arrangements for generating first and second laser pulses with a temporal delay, with the degree of the temporal delay depending upon and being controllable by the characteristics (e.g. the optical path length) of the multipass cell that is used. The optical arrangements of the present disclosure may comprise one or a plurality of unpolarising beamsplitters. Additionally or alternatively, the optical arrangement may comprise one or a plurality of polarising beamsplitters. The light may be polarised or unpolarised depending on the combination of beamsplitters that is employed. Such arrangements are advantageous in that they do not require particularly strict alignment between the laser and the optical cavity. Moreover, they can be fabricated efficiently and effectively.

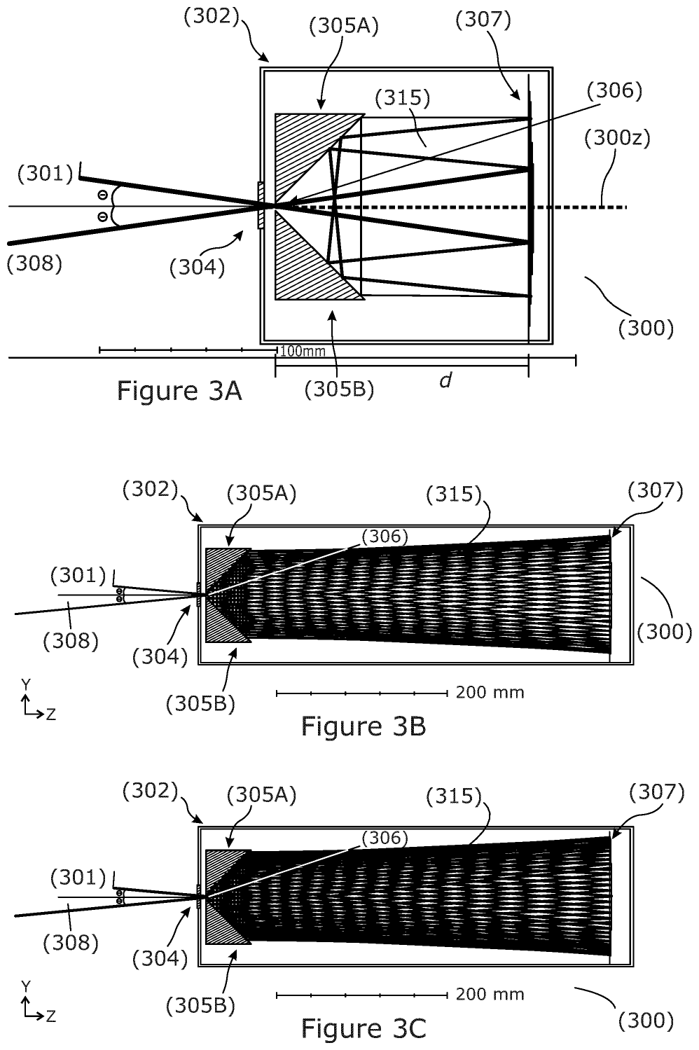

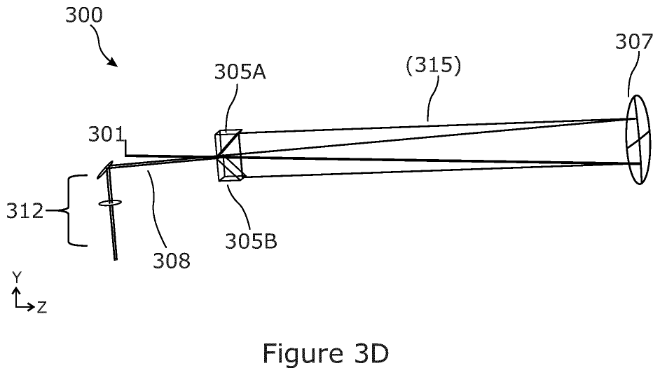

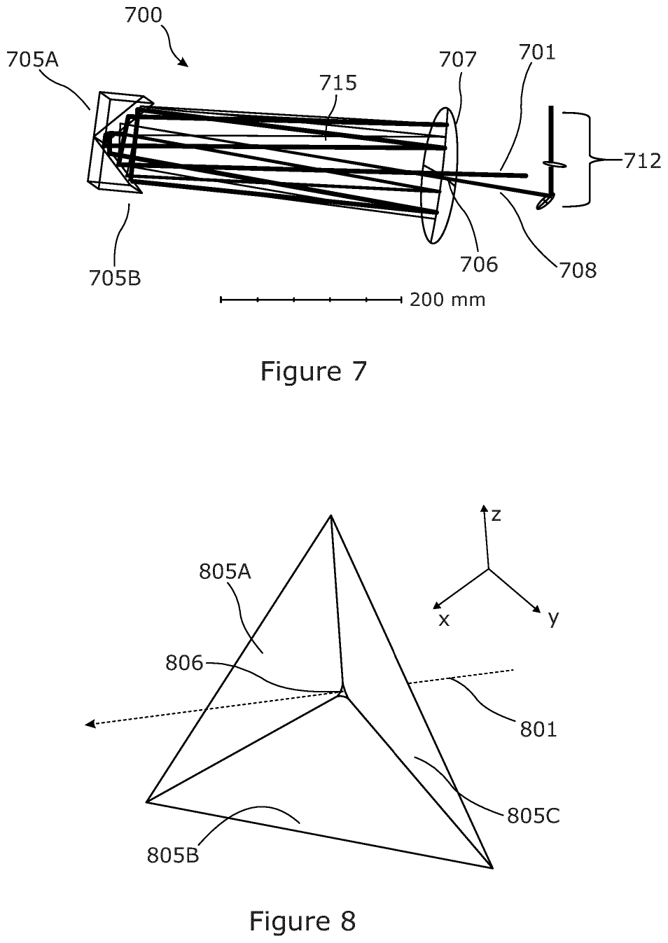

The multipass cell 200 may be any type of existing multipass cell, such as a White or Herriott cell. Multipass cells, such as the White or Herriott cell, are generally used as spectroscopic absorption cells. However, the present disclosure also encompasses novel multipass cell geometries that allow surprisingly long optical delays to be achieved using remarkably mechanically stable cells. Examples of such multipass cells are depicted in FIGS. 3A to 3D and 7, which are discussed in greater detail below.

In contrast to existing multipass cells, the novel multipass cells for use in the laser systems of the present disclosure may comprise, in generalised terms: a first reflector arrangement; and a second reflector arrangement; wherein the first reflector arrangement is configured such that light incident on the first reflector arrangement is at least partially retroreflected towards the second reflector arrangement. Advantageously, the use of a reflector arrangement that is at least partially retroreflective provides the effect of improved mechanical stability, because a partially retroreflective surface inhibits scattering of light incident thereon and so light is reflected back to its source with reduced or minimum scattering. In this case, light is reflected from the first reflector arrangement towards the second reflector arrangement, which allows the multipass cell of this disclosure to tolerate more mechanical misalignment than prior art devices, which cannot tolerate significant misalignment.

The first reflector arrangement of the present disclosure may be defined in alternative terms based on its structure rather than its partial retroreflectivity. For example, the first reflector arrangement may be defined as having two perpendicular (or substantially perpendicular so as to provide partial retroreflectivity) reflective surfaces or three mutually perpendicular (or substantially perpendicular so as to provide retroreflectivity) reflective surfaces. A planar mirror reflects light incident thereon back to its source only when the light is exactly perpendicular to the mirror, having a zero angle of incidence. Whilst laser light exhibits a low degree of beam (or pulse) divergence, no laser beam is perfectly collimated. Moreover, no mirror is perfectly planar. Therefore, for real light sources, some scattering from a planar mirror typically occurs. Thus, in the context of this disclosure, a planar mirror is not considered to be partially retroreflective. Rather, in the context of this disclosure, a reflector arrangement is at least partially retroreflective if it provides a retroreflective action for light across a range (i.e. a plurality) of angles of incidence (unlike a perfectly planar mirror, which can only retroreflect light incident at a single angle of incidence).

Retroreflectivity can be obtained using a corner reflector, which comprises three perpendicular planar reflectors that cause any light incident into the corner reflector to be retroreflected to its source. Partial retroreflectivity can also be achieved using only two perpendicular planar mirrors and in this case, light incident from a range of directions will be retroreflected. However, the lack of a third reflective surface means that light having a component in the direction defined by the line of intersection of the two planes will not be perfectly retroreflected to its source. Rather, two planar perpendicular mirrors are retroreflective for light that is perpendicular to the direction defined by the intersection of the two planes.

A multipass cell 300 for use in the laser systems of the present disclosure is depicted in FIGS. 3A, 3B, 3C and 3D, which show schematically the multipass cell 300 in four different configurations.

The multipass cell 300 comprises a housing 302. Light 301, which is typically coherent light (e.g. light generated by a laser), enters the housing 302 through an optical window 304, which is transparent to the selected wavelength of the light source. The optical window 304 may simply be an aperture in the housing 302. The light 301 can be a second laser pulse that has been split from a single laser pulse by a beam splitter arrangement as shown in FIG. 2. The light 301 is directed at an incoming entry angle Θ with respect to the normal to the window 304. The angle Θ is also the angle between the direction of the light 301 and the longitudinal axis 300z of the cell. The longitudinal axis 300z is shown in FIG. 3A but is omitted from FIGS. 3B, 3C and 3D for simplicity. The angle Θ is typically from 2° to 10° (although other ranges of angles can be used).

The multipass cell 300 comprises first and second reflector arrangements 305 and 307. The reflector arrangements 305 and 307 are arranged such that light entering the multipass cell 300 is repeatedly reflected between the two arrangements (without being reflected from any surfaces other than the surfaces of the two reflector arrangements) and the reflector arrangements 305 and 307 define an optical cavity 315.

The first reflector arrangement 305 comprises two prism mirrors 305A, 305B positioned such that a small slit 306, which is typically 2 to 10 mm wide, is defined between the prisms 305A and 305B. The first reflector arrangement comprises two surfaces (faces of the two prisms) that are substantially perpendicular. The slit 306 is aligned with the window 304 and serves as an aperture through which a beam or pulse of light can enter and exit an optical cavity 315 defined within the multipass cell 300.

The second reflector arrangement 307 of this cell 300 is a spherical, circular mirror, which is positioned at a distance d from the prism mirrors 305A and 305B. In this cell 300, the second reflector arrangement 307 does not have an aperture and so light cannot pass through the second reflector arrangement. The second reflector arrangement 307 faces the prisms 305A and 305B of the first reflector arrangement.

In use, light 301 enters the cell through the optical window 304 and the slit 306 between the prisms 305A and 305B. The light then reflects from the spherical mirror 307, which reflects and focuses the light back towards the first reflector arrangement 305. The light reflects from one of prisms 305A and 305B to the other of the prisms 305A and 305B and, because the prisms 305A and 305B are positioned such that their faces are perpendicular, the light is retroreflected by the combination of the two prisms back towards the spherical mirror 307. The symmetry of the reflector arrangements 305 and 307 causes the light to follow a specific path within the cell 300 and this path is remarkably stable with respect to misalignment. After a number of reflections within the optical cavity 315, the path of the light is eventually incident upon the slit 306 between the prisms and so the light 308 emerges from the cell 300. When the optical cavity 315 is viewed in cross-section (in the plane perpendicular to the axes of the prisms 305A and 305B; or equivalently in the plane whose normal vector is the line of intersection of the planar reflecting surfaces of prisms 305A and 305B), the angle Θ at which the light 308 emerges from the cell 300 is equal (but in the opposite direction) to the angle at which the light 301 enters the cell 300.

Hence, the combination of the two prism mirrors 305A and 305B and the spherical mirror 307 defines a set of standing modes that can trap light within the cell 300 for a number of reflections before exiting the cavity 315 along the exit direction of the light 308. The number of reflections and consequently the total achievable optical path length within the multipass cell 300 depends on a number of factors including: the surface areas of the prism mirrors 305A, 305B; the radius of curvature of the spherical mirror 307; the angle at which the light 301 enters the cavity 315; and the distance, d, between the prism mirrors 305A, 305B and the spherical mirror 307. Thus, the optical path length depends on the geometrical characteristics of the setup. However, the optical path length is not affected by the physical characteristics of the light (including wavelength, beam energy per unit area, or whether the light 301 is pulsed or continuous-wave).

The effects of the geometry on the optical path length are shown in FIGS. 3A to 3D, which depict simulated ray traces for different configurations. In FIG. 3A, the separation between the first and second reflector arrangements 305 and 307 is d=150 mm. This is the distance between the centre of the aperture between the two prism mirrors 305A and 305B and the spherical mirror 307. This arrangement leads to 8 reflections and a total optical path length of 1.2 m. In FIG. 3B, the distance d is increased to 485 mm, leading to 66 reflections and a total optical path length of 31.9 m. In FIG. 3C, the distance d has been further increased to 525 mm, leading to 88 reflections and a total optical path length of 46.3 m. The angles of incidence in FIGS. 3B and 3C are the same as in FIG. 3A.

FIG. 3D shows a special case for the multipass cell 300 in which the distance d is equal to exactly half of the focal length of the second reflector arrangement 307 (which in this case is a circular mirror). It can be seen that in this arrangement, the incident light 301 passes through the first reflector arrangement 305 and strikes the second reflector arrangement 307, before being reflected back towards the first reflector arrangement 305. The first reflector arrangement 305 then partially retroreflects the light back towards the second reflector arrangements and, due to the high degree of symmetry of this configuration, the light returns to the centre of the first reflector arrangement where it emerges from the optical cavity 315 along the direction of the exiting light 308. Ensuring that the first and second reflector arrangements 305 and 307 are separated by half the focal length of the second reflector arrangement 307 causes the light to traverse the length of the cell 300 exactly four times.

FIG. 3D is simplified and omits the housing of the FIGS. 3A, 3B and 3C. However, FIG. 3D further illustrates an optical arrangement 312 for guiding the light 308 emerging from the cell 300 to a desired destination (e.g. to a sample for analysis in a LIBS system). In this case, the optical arrangement 312 comprises a mirror and a lens, but various combinations of optical elements may be used to direct light to a desired destination.

The multipass cell 300 of FIGS. 3A to 3D therefore provides a novel architecture based on the combination of two prism mirrors 305A and 305B and a concave spherical mirror 307. It can be seen from these figures that a wide range of optical path lengths are achievable. This architecture may be used to provide relatively long optical delays between laser pulses in LIBS and may provide an optical path length of up to or greater than 50 metres (equivalent to a temporal delay of approximately 167 ns).

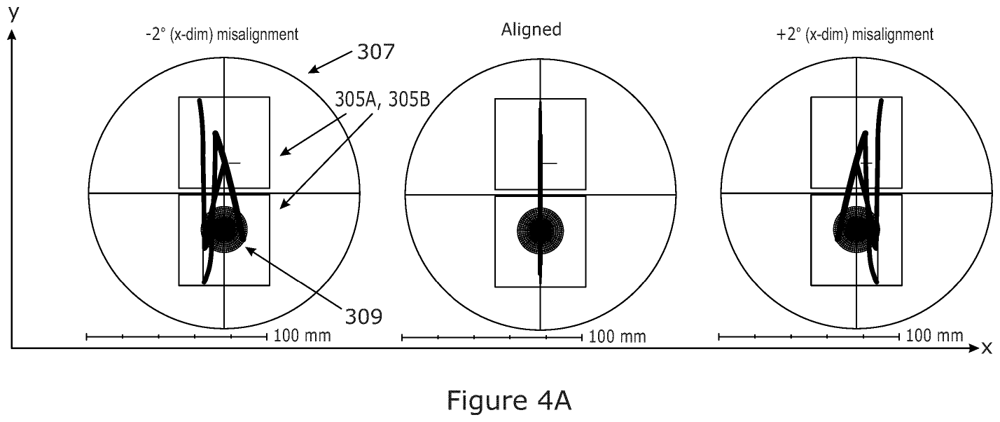

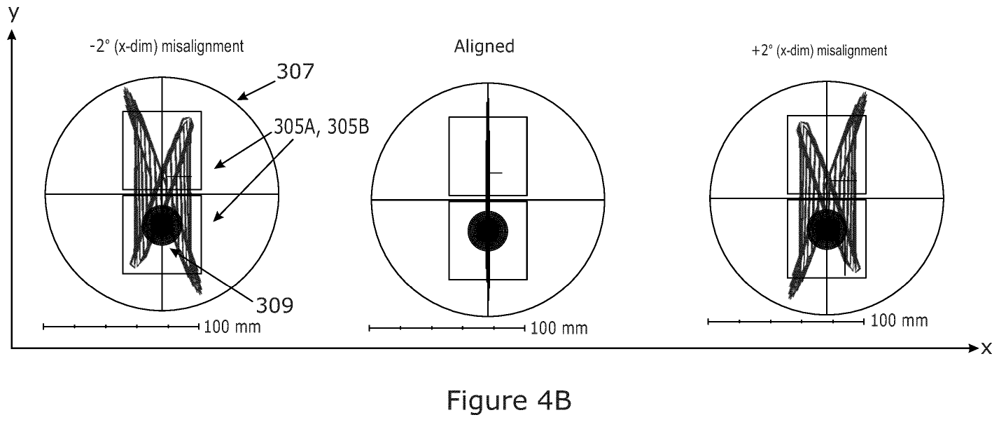

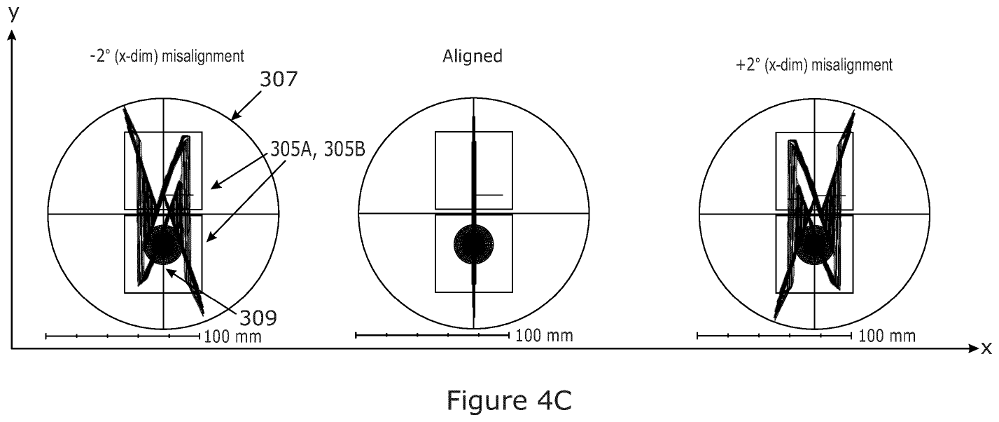

FIGS. 4A, 4B and 4C depict simulations of the multipass cell 300 of FIGS. 3A to 3D when slightly misaligned. As noted previously, an advantage provided by embodiments of this disclosure is the increased stability when up to 4° of misalignment between the reflector arrangements is present. This can be demonstrated by studying the effects of controlled misalignment on the optical path traced by a coherent light beam.

Each of FIGS. 4A, 4B and 4C is composed of 3 subfigures outlining a different misalignment scenario. FIG. 4A shows a stability study of the multipass cell for the geometry presented in FIG. 3A, with a separation between the reflector arrangements 305 and 307 of d=150 mm. FIG. 4B is a stability study of the multipass cell for the geometry presented in FIG. 3B, with a separation between the reflector arrangements 305 and 307 of d=485 mm. FIG. 4C is a stability study of the multipass cell for the geometry presented in FIG. 3C, with a separation between the reflector arrangements 305 and 307 of d=525 mm.

In each case, the central subfigure corresponds to a well-aligned laser beam that follows an optical path on a single plane by creating standing modes between the prism mirrors 305A and 305B and the spherical mirror 307. For the stability analysis depicted in FIGS. 4A to 4C, the exiting beam is collected onto a detection system 309.

When the beam is misaligned in the x-dimension from −2° (left subfigure) to +2° (right subfigure), the optical path is no longer confined to a single plane and can span the entire volume between the prism mirrors 305A and 305B and the spherical mirror 307. The geometry proposed in the multipass cell 300 allows the integrity of the standing modes to be maintained under misalignment, which means the beam may successfully exit the cell 300 even under severe misalignment conditions. In each of FIGS. 4A, 4B and 4C, a beam with an incoming misalignment angle of up to 4° in the x-dimension −2° to +2°) is shown. This results in the optical path being tilted with respect to the aligned case, where all reflections lie on a single plane. Within these boundaries, the beam is nevertheless able to create standing modes within the multipass cell and successfully exit for detection at a detection system 309.

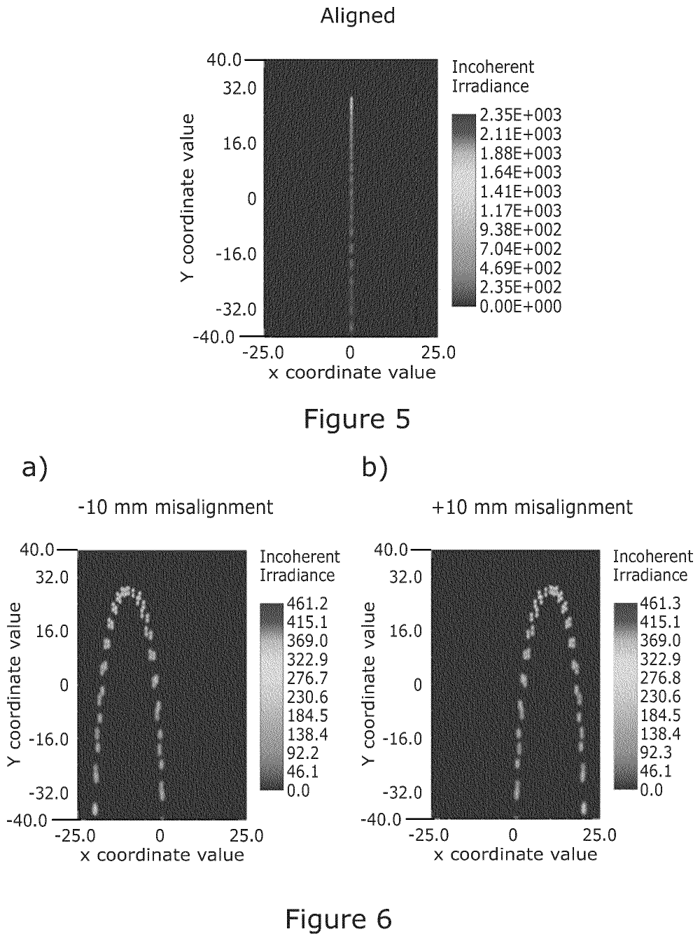

FIGS. 5 and 6 show a further study of the stability of the geometry of the multipass cell 300, in which a misalignment is applied to the spherical mirror 307 in the x-dimension, as shown in FIG. 6, and in which the spherical mirror is perfectly aligned, in FIG. 5. The mirror 307 is considered to be aligned if its centre lies on the same segment originating from the source of the light 301 and passing across the centre of the slit 306 (between the prisms 305A and 305B). The mirror 307 is moved away from this segment by 10 mm in the positive direction and then by 10 mm in the negative direction. The stability of the system is demonstrated by simulating the impact location of the light on the prism mirror 305A as a function of these misalignments. The behaviour on the prism mirror 305B is analogous.

FIG. 5 corresponds to the case in which no misalignment occurs. In this case, the standing modes within the cavity 315 are located onto a single line over the prism mirror 305A. When negative (FIG. 6(a)) or positive (FIG. 6(b)) misalignments of 10 mm occur, the standing modes move from a single line and form a set of two parabolas. The light traverses the two parabolas in sequence, one after another. This is important and allows the entry point and the exit point of the light to coincide, which is important for the stability of the cell 300.

An advantage of providing a highly stable multipass cell 300 is that the optical path length traversed by light in the cell 300 is easily adjustable by changing the distance d between the spherical mirror 307 and the two prism mirrors 305A and 305B. The benefits of increased optical path length include the ability to provide long optical delays between laser pulses. Thus, it can be seen from FIGS. 4A to 4C, FIG. 5 and FIG. 6 that the multipass cell 300 of FIGS. 3A to 3D provides a stable system that can provide long optical path lengths even in the presence of misalignment between the optical components. However, a number of features of the multipass cell of FIGS. 3A to 3D may be omitted or modified whilst retaining these advantages.

For example, it will be appreciated that the housing 302 and the optical window 304 may be omitted entirely. Moreover, the advantage of improved stability can be achieved using two planar mirrors that are substantially perpendicular, rather than prisms 305A and 305B. Such an arrangement would provide the same effect of being partially retroreflective for light incident thereon. Furthermore, the aperture 306 through which light enters the cavity 315 can be placed in the second reflector arrangement rather than the first reflector arrangement. Additionally, the spherical mirror 307 need not be spherical and could have various other forms whilst benefiting from the partially retroreflective prisms 305A and 305B. Thus, it can be seen that the multipass cell 300 is one specific example of an advantageous arrangement but that various alterations and variations may be made.

Hence, returning to the generalised terms used previously, the first reflector arrangement of this disclosure preferably comprises first and second surfaces that are reflective. The first reflector arrangement may be configured such that light incident thereon is reflected from the first surface to the second surface, and to the second reflector arrangement. Light reflected from the second surface may be incident on a third surface of the first reflector arrangement before being reflected to the second reflector arrangement, or the light reflected from the second surface may be reflected directly to the second reflector arrangement without being reflected by any further surfaces.

The first and second surfaces are preferably substantially perpendicular. The first and second surfaces are preferably substantially planar. This arrangement can be used to provide a retroreflective action on light to improve the mechanical stability of the multipass cell. Perfectly planar, perpendicular surfaces will exhibit full retroreflectivity but some deviations from perfectly planar, perpendicular surfaces may be tolerated. For instance, the surfaces may deviate from being perfectly planar and/or perfectly perpendicular, provided that the effect of (at least) partial retroreflectivity is still achieved. When light possesses some components non-normal to the surface of the second reflector arrangement (e.g. a spherical mirror), then this will enter in the cavity and can form a set of standing wave-like patterns, as shown in FIGS. 4A to 4C, FIG. 5 and FIG. 6.

Furthermore, there is no requirement for the entire first or second surface to be entirely planar. For instance, one or both of the surfaces may have a curved portion (e.g. at the edge or edges) in addition to a planar portion. In this case, provided that the substantially planar portions of the first and second surfaces are substantially perpendicular to one another, they can still work together to partially or fully retroreflect light incident thereon.

Thus, the disclosure provides a multipass cell comprising: a first reflector arrangement; and a second reflector arrangement; wherein the first reflector arrangement comprises first and second surfaces that are reflective, wherein the first and second surfaces are substantially perpendicular and/or substantially planar.

The planes of the first and second surfaces may define a common axis and the first reflector arrangement may be retroreflective for light incident perpendicular to the common axis. In the context of planar surfaces, the common axis is the line of intersection defined by the planes containing the planar surfaces. Any two non-parallel planes define a line of intersection. Therefore, even if two planar surfaces do not actually intersect, the planes in which the surfaces lie will define an axis of intersection. The axis of intersection may be considered to be the line along which the planar surfaces would intersect if the planes had infinite spatial extent.

Preferably, the first reflector arrangement comprises first and second prisms and the first and second surfaces are faces of the first and second prisms respectively. Prism mirrors are widely available optical components that allow the advantageous embodiments described previously to be manufactured accurately and easily. For example, the prism mirrors may have a cross-section that is a right-angled isosceles triangle (i.e. with interior angles of 90°, 45° and 45°). In this case, by placing two such prisms adjacent one another, with both prisms resting on their shorter (non-hypotenuse) face, a partially retroreflective surface (defined by the two surfaces of the prisms that will be perpendicular in this arrangement) can be fabricated easily. Thus, the multipass cells of this disclosure advantageously use inexpensive, commercially available components to provide a cost-effective and reliable method for manufacturing a stable multipass cell.

The second reflector arrangement is preferably configured such that light incident thereon is reflected towards the first reflector arrangement. For example, the second reflector arrangement may be configured such that light received from the first reflector arrangement is reflected to the first reflector arrangement and, because the first reflector arrangement is at least partially retroreflective, light may be made to repeatedly bounce between the first and second reflector arrangements. This may be achieved by ensuring that the first and second reflector arrangements face one another. For example, the first reflector arrangement is at least partially retroreflective and is therefore retroreflective for light received from a range of directions. Accordingly, the second reflector arrangement may be positioned within the range of directions for which the first reflector arrangement is retroreflective. When the second reflector arrangement has a concave face, this face may be facing the at least partially retroreflective portion of the first reflector arrangement. In this way, the first and second reflector arrangement can define a stable optical cavity.

The second reflector arrangement is preferably configured such that light incident thereon is focused towards the first reflector arrangement. The focusing action of the second reflector arrangement works together with the retroreflective action of the first reflector arrangement to inhibit the spreading of light and improve stability. The relationship between the spacing of the reflector arrangements and the focal length of the second reflector arrangement will influence the number of passes traversed by light within the cell.

The second reflector arrangement may comprise a concave surface that is reflective. The concave surface may be an ellipsoidal surface, a spheroidal surface, or a spherical surface. For example, an ellipsoidal reflector having one elongate axis parallel to the line of intersection defined by two reflective planar surfaces could be used. In such a case, the elongated axis would affect the mechanical tolerances as the useful surface to compensate for misalignment would be elongated in one direction and shortened in the other direction. Thus, surfaces with a higher degree of spatial symmetry provide improved stability and consequently, a spherical surface (i.e. a portion of the surface of a sphere with an opening for allowing light in) is most preferred. Minor deviations from spherical may be tolerated. The combination of two plane prism mirrors with a spherical (i.e. centrally symmetrical) mirror provides most improved stability as it means that a slight misalignment of the spherical mirror will not be further amplified, and the light path will still lie in between the volume within the mirrors of the cavity.

Advantageously, in this disclosure, the separation between the first and second reflector arrangements is adjustable. Hence, the multipass cell is configured such that the optical path length traversed by light is adjustable. Whilst not shown in FIGS. 3A to 3D for the purposes of simplicity, the first and second reflector arrangements 305 and 307 are relatively moveable (e.g. by moving one or both). This allows the separation to be controlled and hence the optical path length to be adjusted. The relative motion may be provided by, for example, actuating one or both of the reflector arrangements. The optical path length may be adjustable by changing the number of times light traverses the multipass cell. For instance, increasing the separation may lead to an increase in the distance traversed by light within a single pass, but it may also cause the light to traverse a different number of passes within the cell, further increasing the optical path length. The improved stability of the disclosure allows relatively long optical path lengths to be obtained whilst providing control over the path length.

Using the cells of the present disclosure, the optical path length is adjustable to: greater than or equal to 30 cm (and preferably no more than 1 m, 5 m, 15 m, 25 m, 40 m, 50 m, or 100 m); greater than or equal to 1 m (and preferably no more than 5 m, 15 m, 25 m, 40 m, 50 m, or 100 m); greater than or equal to 5 m (and preferably no more than 15 m, 25 m, 40 m, 50 m, or 100 m); greater than or equal to 15 m (and preferably no more than 25 m, 40 m, 50 m, or 100 m); greater than or equal to 25 m (and preferably no more than 40 m, 50 m, or 100 m); greater than or equal to 40 m (and preferably no more than 50 m, or 100 m); greater than or equal to 50 m (and preferably no more than 100 m); or greater than or equal to 100 m (and preferably no more than 150 m). These may be converted into equivalent temporal values by noting that the speed of light is approximately 3×10⁸ ms⁻¹.

The described embodiments exhibit unexpectedly high mechanical tolerances to provide a multipass cell that is suitable to withstand vibrations and simplify mechanical alignment in industrial implementations. The advantages of this disclosure compared to previous multipass cells are numerous and include the increased stability up to 4° (approximately 70 milliradians) of misalignment, long optical path lengths that can be adjusted easily, and an architecture that is simple to manufacture reliably and efficiently.

In the multipass cell 300 of FIGS. 3A to 3D, FIGS. 4A to 4C, FIG. 5 and FIG. 6, the aperture 306 through which light enters the optical cavity 315 is positioned between the two prisms 305A and 305B of the first reflector arrangement 305. However, FIG. 7 depicts an alternative multipass cell 700 in which many of the advantages described previously are achievable by providing an aperture 706 in a second reflector arrangement 707, rather than between the prisms 705A and 705B.

The multipass cell 700 of FIG. 7 comprises a first reflector arrangement 705 that comprises two prism reflectors 705A and 705B, which are positioned such that two faces of the prisms 705A and 705B are perpendicular and provide a partially retroreflective surface. A second reflector arrangement in the form of a spherical mirror 707 is provided facing the prisms 705A and 705B. The spherical mirror 707 comprises a central aperture 706 for allowing light into and out of the optical cavity 715 of the multipass cell 700. Light entering 701 the cell 700, such as a second laser pulse that has been split from a single laser pulse by a first beam splitter arrangement as shown in FIG. 2, is repeatedly reflected between the first 705 and second 707 reflector arrangements before exiting the cavity 715 via the aperture 706 along the direction of the exiting light 708. Due to the high degree of geometric similarity, the standing modes provided by the first 705 and second 707 reflector arrangements are similar to the arrangements 305 and 307 of the multipass cell 300 of FIGS. 3A to 3D. Light emerging from the cell is then directed to its destination via an optical arrangement 712, which is shown as comprising a mirror and a lens in FIG. 7. For example, the light (e.g. second laser pulse) may be directed to a second beam splitter, from where it is directed to a sample (e.g. in a collinear direction to a first laser pulse) as shown in FIG. 2. The multipass cell 700 of FIG. 7 provides the benefits of improved stability and adjustability as the cell 300 of FIGS. 3A to 3D.

Turning next to FIG. 8, there is depicted a reflector arrangement 805 that comprises three planar reflective surfaces 805A, 805B and 805C that are mutually perpendicular. The three surfaces 805A, 805B and 805C define a corner reflector that is retroreflective. An aperture 806 is provided at the corner of the corner reflector 805 to allow light to pass through the corner reflector. Light 801 passing through the rear side of the corner reflector 805 is depicted.

The reflector arrangement 805 of FIG. 8 can be used in multipass cells such as those of FIGS. 3A to 3D and 7, in place of prisms 305A and 305B, or in place of prisms 705A and 705B. If the reflector arrangement 805 of FIG. 8 is used in the multipass cell 700 of FIG. 7, then the aperture 806 may be omitted. The reflector arrangement 805 again provides improved mechanical stability due to the use of a retroreflector to inhibit the spreading of light in an optical cavity.

Hence, returning to the generalised language used previously, in the multipass cells of the present disclosure, the first reflector arrangement may further comprise a third surface that is reflective, wherein the first, second and third surfaces are substantially mutually perpendicular. Thus, a corner reflector can be provided to improve mechanical stability.

The first and second reflector arrangements may define an optical cavity, and at least one of the first and second reflector arrangements preferably comprises an aperture for allowing light to enter and/or exit the optical cavity. The size of the aperture may be adjustable to provide control over the size of the light beam or pulse that enters the cavity. The aperture can take many forms.

When the first reflector arrangement comprises first and second prisms, a slit between the edges of the first and second prisms may define an aperture. A particular advantage of this arrangement is that it is simple to provide an aperture between two prisms by mounting the prisms such that there is a slit between them, without needing to create an aperture in a reflector (e.g. by making an aperture in a spherical reflector or a corner reflector, which could cause damage or mirror imperfections). Thus, this arrangement is easy to make accurately and without risking damage to delicate optical components. The size of the aperture may be adjusted by actuating the prisms to be closer together or further apart. The prisms may be relatively moveable to provide such adjustment.

When the first reflector arrangement comprises first, second and third surfaces, an opening at a corner of the first, second and third surfaces may define an aperture (e.g. the point at which the planes of the three surfaces intersect). Similarly, an opening at the centre (e.g. a point on the second reflector surface that is substantially aligned with the longitudinal axis of the cell) of the second reflector arrangement may define an aperture. This could be a small hole in the centre of a concave reflective surface, for example. Such apertures allow light to enter and/or exit the optical cavity in arrangements that are mechanically stable. In such cases, the size of the aperture may be adjusted by partially covering the aperture with an opaque material (which may be moveable).

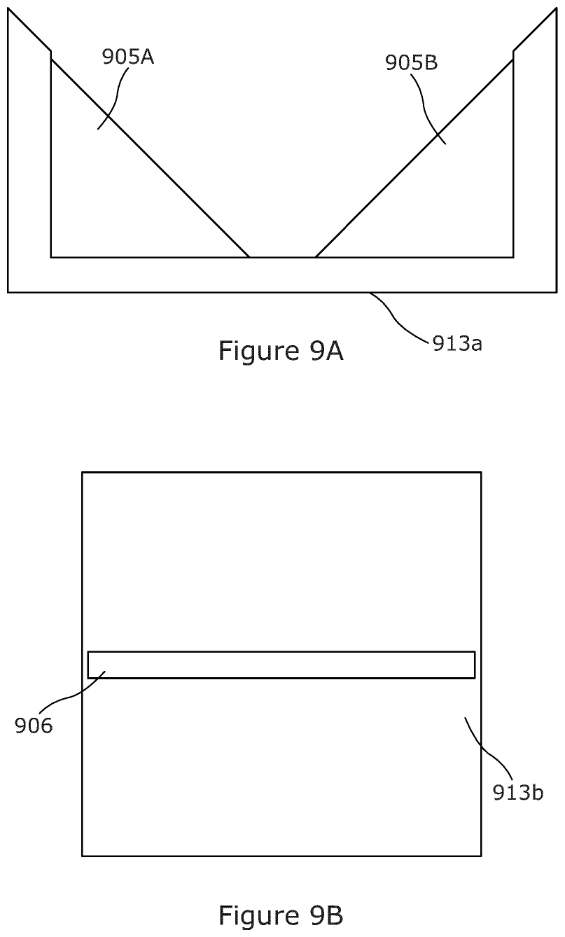

Turning next to FIGS. 9A and 9B, two mounting structures 913a and 913b are depicted for a reflector arrangement 905 comprising two prisms 905A and 905B. The prisms 905A and 905B could be the prisms 305A, 305B or 705A, 705B of the multipass cells 300 or 700 respectively. The mounting structures 913a and 913b can therefore be used in the multipass cells 300 and 700 of FIGS. 3A to 3D and 7.

The mounting structure 913a of FIG. 9A is a frame that is configured to hold the prisms 905A and 905B. The mounting structure 913a in FIG. 9A is shown from one end of the pair of prisms 905A and 905B. The mounting structure may extend along the long edges of the prisms (into the page, along the prism axes) and the opposite end of the mounting structure 913a holds the opposite end of the prisms 905A and 905B in the same way. The mounting structure 913a is dimensioned such that it can hold the non-reflecting edges of the prisms 905A and 905B so as to hold the prisms 905A and 905B securely in position. A minor portion of the mounting structure covers the reflecting surfaces (i.e. the hypotenuse of the prisms 905A and 905B) but the majority of the reflecting surface is exposed so as to allow the prisms 905A and 905B to reflect light within the cell.

The mounting structure 913a may have a friction coating (e.g. rubber) to ensure that the prisms 905A and 905B are held firmly in position. The prisms 905A and 905B may fit within the mounting structure 913a using an interference fit. Alternatively, the prisms 905A and 905B may be held to the mounting structure 913a with an adhesive. In any case, the mounting structure ensures that the reflecting surfaces of the prisms 905A and 905B are substantially perpendicular so as to combine to provide a partially retroreflective surface.

FIG. 9B shows a further mounting structure 913b that may be used in addition to or instead of the mounting structure 913a of FIG. 9A. The mounting structure 913b of FIG. 9B may serve as the base of the mounting structure 913a of FIG. 9A or the mounting structure 913b may itself be a standalone component. The mounting structure 913b of FIG. 9B comprises a flat portion of material to which prisms 905A and 905B may be attached. The mounting structure 913b comprises a slit 906 for allowing light to pass through. The prisms 905A and 905B may be mounted either side of the slit 906 such that the faces of the prisms 905A and 905B are substantially perpendicular. Thus, a partially retroreflective reflector arrangement can easily be provided using a single sheet of material with a slit in it, and two prisms 905A and 905B, which are standard optical components.

The mounting structures 913a and 913b of FIGS. 9A and 9B may be used to ensure that the relative angle between the two prism mirrors 905A and 905B is zero or substantially zero (e.g. close enough to zero to ensure that at least partial retroreflectivity is obtained). In such a case, the two mirrors can together rotate by up to +/−1° approximately and still provide a stable multipass pattern when used with the previously-described multipass cells. However, if the relative angle between the two prism mirrors is larger than 0.1°, then the pattern may be negatively affected. The use of such a mounting structure can ensure that the relative angle between the prisms 905A and 905B is zero or close enough to zero to provide good performance. The mounting structures 913a and 913b of FIGS. 9A and 9B may be formed from various materials (e.g. metal such as aluminium) and using various construction techniques (e.g. welding, moulding or 3D printing).

Hence, in the generalised language used previously, the first reflector arrangement preferably comprises a mounting structure configured to mount the first and second prisms such that the first and second surfaces are substantially perpendicular. The use of a mounting structure can help to ensure that the surfaces are positioned correctly to within an acceptable degree of misalignment.

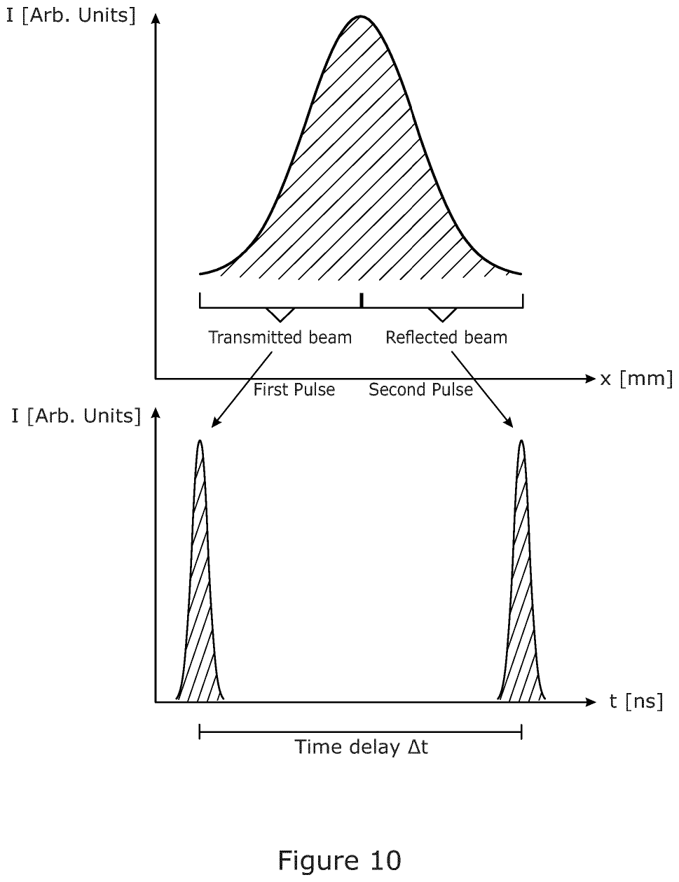

In FIG. 10, the principle of mechanical beam splitting is depicted. The top graph represents a one-dimensional spatial section of a Gaussian laser pulse at an instant in time. The bottom graph displays the temporal profiles of two pulses formed from splitting the top pulse, which are separated by a time delay. The present disclosure proposes the use of a reflective surface to mechanically split a single pulse generated by a pulsed laser into a double (preferably collinear) set of two pulses and to be introduced a delay using a multipass cell. The transmitted portion of the beam (i.e. the left portion of the pulse depicted in the top graph of FIG. 10) is not subjected to any delay and is therefore positioned to the left along the temporal axis of the lower graph of FIG. 10. A reflected beam or pulse (i.e. the rightmost portion of the pulse depicted in the top graph) is subjected to a delay and so is positioned to the right on the temporal axis in the lower graph of FIG. 10. Thus, it can be seen that a time delay Δt can be introduced between two laser pulses generated by mechanically splitting a single laser pulse. Therefore, a double-pulse laser architecture can be provided.

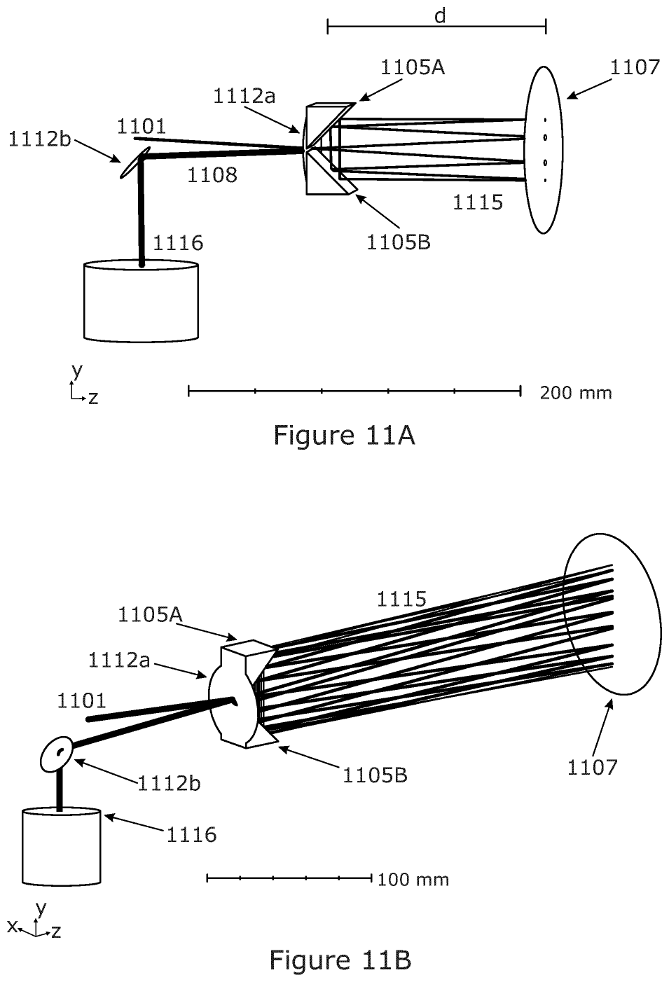

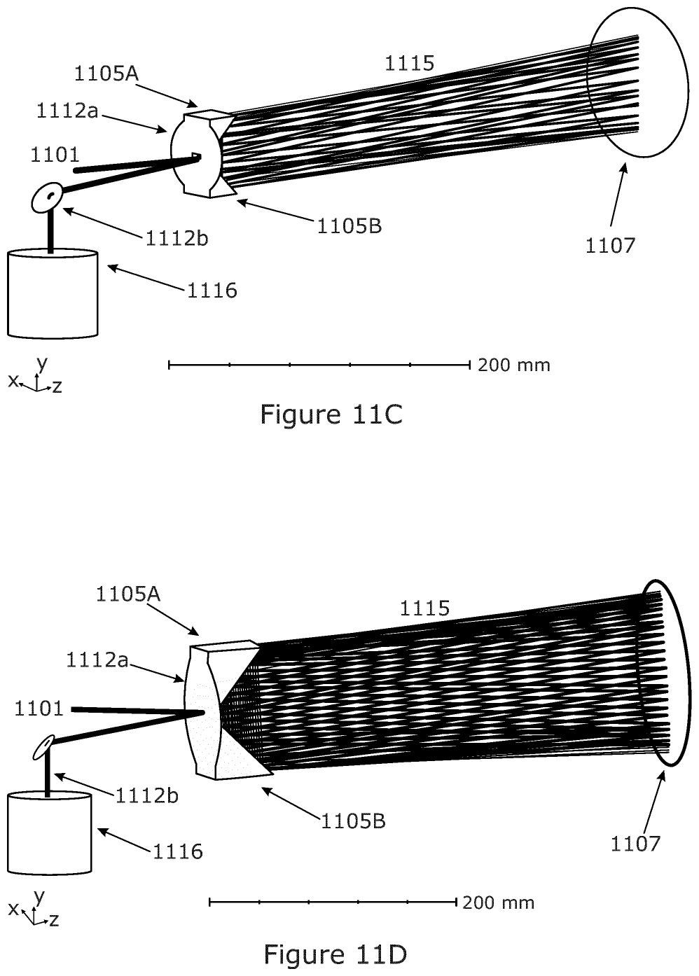

FIGS. 11A to 11D demonstrate how the mechanical beam splitting principle of FIG. 10 can be applied in combination with the multipass cells of this disclosure, as an alternative to the beam splitting using the beamsplitter arrangements of FIG. 2. For instance, in FIGS. 11A, 11B, 11C and 11D, there are depicted four configurations of a double-pulse laser system for generating first and second laser pulses. Because the multipass cell provides a relatively long optical path length when compared with existing multipass cells, the cell effectively functions as a delay line that introduces a relatively long time delay between two laser pulses. Moreover, the geometry of the cell ensures that the light 1108 emerging from the cell is collinear with the light reflected from the exterior surface 1114 of the cell.

The double-pulse laser system of FIGS. 11A to 11D is similar to the previously-described systems in that it comprises a multipass cell having two prisms 1105A and 1105B and a spherical reflector 1107 that define an optical cavity 1115. Light 1101 enters the cell at a slight angle, as described previously. The double-pulse laser system also comprises an optical arrangement 1112 for guiding the light 1108 emerging from the cell towards a target destination 1116, which could be a sample. The optical arrangement comprises a mirror 1112b. An important difference between the double-pulse laser system and the previously-described multipass cells is that the exterior surface of the prisms 1105A and 11058 is reflective and comprises a small aperture (aligned with the slit between the prisms 1105A and 1105B) for allowing light 1101 into the cell. This reflective surface with an aperture acts as an optical splitting device 1112a for splitting light and forms part of the optical arrangement 1112.

More specifically, in the schematic setup of the double-pulse system of FIGS. 11A to 11D, a collimated and pulsed laser beam 1101 is directed towards a planar mirror 1112a on the exterior (rear surface) of the prisms 1105A and 11058. The pulsed laser beam path is represented in FIGS. 11A to 11D as solid continuous lines, although these lines should not be mistaken for a continuous wave laser emission. The angle of the pulsed beam 1101 is slightly tilted with respect to the normal of the mirror 1112a and is typically 2-6°. The normal of the mirror 1112a is parallel to the axis of the cell, (i.e. the longitudinal axis extending between the slit between the prisms 1105A and 11058 and the centre of the spherical mirror 1107).

The mirror 1112a comprises a central, circular aperture of 1 mm diameter, allowing part of the laser pulse 1101 to be sampled through it and part of the laser pulse 1101 to be reflected from it along the path 1108. Similarly to the previously-described embodiments, the angle of light 1108 emerging from the cell (relative to the normal of the aperture) is the same magnitude but the opposite direction to the angle of the incoming light 1101, which arises due to the geometry of the cell.

The aperture of the optical splitting device 1112a is dimensioned so that an incoming light pulse 1101 is split (e.g. divided into two distinct pulses), with approximately half of the light being reflected from the exterior surface 1114 towards the optical arrangement 1112b and half of the light entering the cell, where it is reflected multiple times before ultimately leaving the cell and reaching the optical arrangement 1112b. Whilst the aperture is 1 mm in diameter in FIGS. 11A to 11D, other widths (e.g. diameters of 0.5 mm, 1.5 mm, 2 mm, 2.5 mm and so on) may be used depending on the width of the laser beam used. In the specific systems depicted in FIGS. 11A to 11D, the pulsed laser beam 1101 possesses a Full-Width-At-Half-Maximum (FWHM) of 1 mm.

The system is configured such that the pulse 1101 is centred on the edge of the aperture of mirror 1112a, and the mirror 1112a has a radius of 25 mm (i.e. of a similar size to the prisms 1105A and 1105B). Various optical elements could be used to direct the pulse 1101 to the mirror 1112a in this way. Half of the pulse is reflected by the surface of the mirror 1112a while the other half passes through the aperture. The reflected pulse is directed towards the planar mirror 1112b and then towards the surface of a sample 1116. The transmitted pulse is directed towards the spherical, concave mirror 1107 of the cell, which has a radius of curvature r=1000 mm and a diameter of 50 mm. This mirror 1107 reflects and focuses the pulse back towards the two right-angle prism mirrors 1105A and 1105B, as shown in FIGS. 11A to 11D. The two right-angle prism mirrors 1105A and 1105B have a segment size of 25 mm. In this context, the segment size is the length of the two sides of the right-angled triangle that meet at right angles (i.e. the length of the non-hypotenuse lengths of the triangular cross-section of the prisms 1105A and 1105B). The combination of the mirrors 1105A, 1105B and 1107 forms a cavity 1115 system, where the pulse that enters through mirror 1112a is reflected back and forth for a number of times before eventually exiting from the aperture of the mirror 1112a.

The total optical path length difference (OPD) provided by the systems of FIGS. 11A to 11D is defined as the difference between: a) the distance covered by the pulse that passes through mirror 1107 and which is reflected inside the cavity 1115 before exiting from the central aperture of mirror 1112a and reaching the sample 1116; and b) the distance travelled by the part of the pulse that is reflected at mirror 1112a before reaching the sample 1116. Advantageously, the OPD can be easily tuned by adjusting the distance d between: the first reflector arrangement 1105, comprising (right-angled) prism mirrors 1105A and 1105B; and the second reflector arrangement, which in this case is mirror 1107. The OPD can be controlled by adjusting just the separation d whilst leaving the geometry of the other components unchanged. By adjusting the OPD, the temporal delay Δt between the first pulse (reflected by mirror 1112a) and the second pulse (transmitted through mirror 1112a) can be adjusted.

The system of FIG. 11A can be adjusted to various configurations, as shown in FIGS. 11B, 11C and 11D, and can be simulated to investigate the OPDs and temporal delays that are attainable. In the simulations, the laser pulse is taken to be Gaussian, collimated, unpolarised, with a wavelength of 532 nm, and composed by a number of rays equal to 10⁴ to achieve statistical significance. In FIG. 11A, a distance d=150 mm causes the transmitted pulse to be reflected 4 times and this leads to an OPD of 1.13 m and a corresponding Δt=3.8 ns. In FIG. 11B, a distance d=300 mm causes the transmitted pulse to be reflected 21 times and leads to an OPD of 6.75 m and a corresponding Δt=22.5 ns. In FIG. 11C, a distance d=400 mm causes the transmitted pulse to be reflected 28 times and leads to an OPD of 12.46 m and Δt=41.5 ns.

As the distance d increases and as the number of reflections increase, the tolerances required for the mechanical alignment of the optical system become more demanding. This is of the order of ˜1.5 mm and ˜2° rotation angle (x,y) for the layout displayed in FIG. 11A, ˜1 mm and ˜1° angle for the layout displayed in FIG. 11B and ˜0.5 mm and ˜0.5° angle for the layout displayed in FIG. 11C. The required alignment limits the OPD that can be achieved. Nevertheless, such alignments are readily attainable using the systems of the present disclosure and temporal delays Δt on the order of 50 ns can therefore be achieved. The temporal delays achieved using the multipass cell therefore can be 1 ns or greater (for example up to 10 ns, up to 50 ns, up to 80 ns, up to 100 ns, up to 150 ns, or greater than 150 ns), or 5 ns or greater (for example up to 10 ns, up to 50 ns, up to 80 ns, up to 100 ns, up to 150 ns, or greater than 150 ns), or 10 ns or greater (for example up to up to 50 ns, up to 80 ns, up to 100 ns, up to 150 ns, or greater than 150 ns), or 50 ns or greater (for example up to 80 ns, up to 100 ns, up to 150 ns, or greater than 150 ns), or 80 ns or greater (for example up to 100 ns, up to 150 ns, or greater than 150 ns), or 100 ns or greater (for example up to 150 ns, or greater than 150 ns). Shorter delays, for example, 0.1 ns or greater can also be obtained depending on the cell design parameters.

To reduce the stringency of the alignment requirements, it is possible to increase the size of the right angle mirrors 1105A and 1105B such that their segment size (the non-hypotenuse dimension) is 50 mm and to increase the size of the spherical mirror 1107 to a diameter of 75 mm. This relaxes the mechanical tolerance requirements and allows higher OPDs to be obtained with comparable distances d. An example of such layout is depicted in FIG. 11D, where a distance d=400 mm causes the transmitted pulse to be reflected 31 times and leads to an OPD of 25.30 m and a corresponding Δt=84.3 ns. The tolerances of this layout are ˜1 mm and 1° (x,y), approximately. Hence, temporal delays on the order of 100 ns (and higher) are readily attainable.

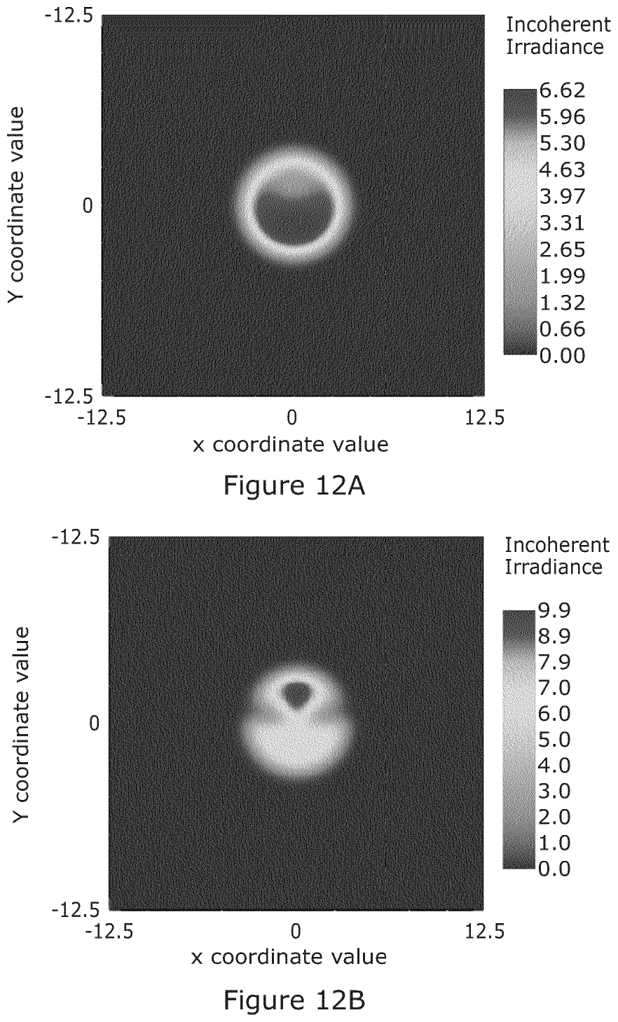

In many applications (e.g. in double-pulse LIBS experiments), it is important that two pulses are incident on the same position (for instance, on a sample's surface). In order to verify the effectiveness of the double-pulse systems, a beam profile study of the example displayed in FIGS. 11A to 11D can be performed, the results of which are displayed in FIG. 12A. The relative beam irradiance is displayed using a colour palette, spanning red (high irradiance) to blue (low irradiance). The results show an excellent circular Gaussian profile in both the x-, and y-dimensions, as shown in FIG. 12A. The profile in FIG. 12A is for a circular aperture. FIG. 12B shows an equivalent beam profile study for a system that is identical to the system used for FIG. 12A except in that the splitting of the laser pulse is performed using parallel mirrors rather than a circular aperture. It can be seen from FIG. 12B that a non-circular aperture leads to a deterioration in the quality of the superimposed pulses. Hence, a circular aperture for splitting a single laser pulse is preferred. In each of FIGS. 12A and 12B, in order to aid visualisation, the graphs display the two pulses superimposed on one another, irrespective of the time required for each of them to hit the target.

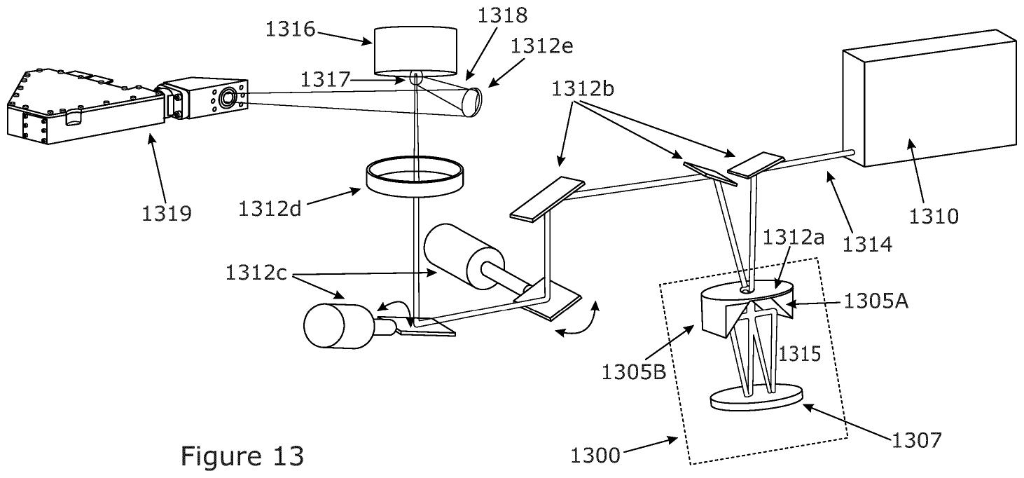

In FIG. 13, there is depicted a double-pulse laser-induced breakdown spectrometry system that operates according to the principles described previously. The LIBS system of FIG. 13 uses a double-pulse laser system such as that depicted in FIGS. 11A to 11D. The system of FIG. 13 comprises a multipass cell 1300, which may be any multipass cell described previously, and which comprises a first reflector arrangement 1305 comprising two prisms 1305A and 1305B and a spherical mirror 1307 defining a cavity 1315.

The system comprises a laser source 1310, which is capable of emitting a single laser pulse 1314. The system also comprises an optical arrangement 1312, which comprises a number of optical elements 1312b-d for guiding light to the cell 1300 and then from the cell 1300 to a sample 1316. The optical arrangement is also configured to generate first and second laser pulses from the single laser pulse 1314 by virtue of an optical splitting device 1312a, which is a reflective surface having an aperture on the first reflector arrangement 1305 of the cell 1300. The optical splitting device 1312a is integrally formed with the first reflector arrangement 1305 of the cell 1300. The optical arrangement 1312 also comprises rotatable mirrors 1312c and lens 1312d for guiding and focusing laser pulses from the cell 1300 to a sample 1316.

It can be seen in FIG. 13 that when a laser pulse 1314 is emitted by the laser source 1310, it is guided by a mirror of the optical arrangement 1312b to the cell 1300. As described previously, part of the single pulse 1314 is reflected by the optical splitting device 1312a to form a first laser pulse and part of the single pulse 1314 passes into the cavity 1315 of the cell 1300 to be delayed with respect to the first pulse, thereby forming a second laser pulse.

Once the first and second pulses are respectively reflected from the splitting device 1312a and emerge from the cell 1300, they are guided by further mirrors of the optical arrangement 1312b to rotatable mirrors 1312c, which can fine-tune the direction of the pulses such that they are directed to the lens 1312d. The lens 1312d then focuses the pulses such that they impact a point on the sample 1316.

The first laser pulse impacts the sample 1316 and generates a plasma 1317 from the surface of the sample 1316 and the second laser pulse then impacts the plasma 1317 to increase its temperature and additionally impacts the surface to generate further plasma. The first and second pulses thus cause the generation of the plasma 1317 and the subsequent emission of plasma light 1318 from the plasma 1317. The plasma light is reflected by a mirror 1312e that is positioned near the sample. The mirror 1312e guides the plasma light to a detector (e.g. a spectrograph) 1319 for analysis of the emissions. The mirror 1317 may be considered to be part of the optical arrangement 1312 or may be a separate optical arrangement.

In the specific example depicted in FIG. 13, the mirrors 1312c are Galvo mirrors (e.g. of a motorised dual-axis galvo system that allows scanning of the position of the laser pulses across the surface in two dimensions, for example to enable surface mapping of the sample) and the lens 1312d is an f-theta lens. However, other types of adjustable mirror and focussing elements may be used. Furthermore, any number of mirrors and/or lenses can be used within the optical arrangement 1312 and additional plasma mirrors 1312e may be used (e.g. to direct emitted light 1318 from the plasma to one or more further detectors, which may be a different type to the detector 1319). Moreover, the optical splitting device 1312a of the optical arrangement 1312 may be replaced by a beamsplitter arrangement, such as the arrangement depicted in FIG. 2.

Hence, it can be seen that first and second laser pulses can be generated using beamsplitters or by mechanical splitting. Therefore, in generalised terms, the optical arrangements of the disclosure may comprise an optical splitting device (e.g. a mechanical beamsplitter rather than a conventional beamsplitter) for generating the first and second laser pulses by splitting a single laser pulse. The optical splitting device may be attached to or integral with the multipass cell. For example, the optical splitting device may be on an exterior surface of the multipass cell. The multipass cell may comprise first and second reflector arrangements defining an optical cavity, and the optical splitting device may be on an exterior surface of one of the first and second reflector arrangements.

The optical splitting device may comprise a reflective surface having an aperture through which at least a portion of a laser pulse can pass. The reflective surface of the optical splitting device may be substantially planar. When prisms are used for the first reflector arrangement, it is straightforward to affix a reflective surface to the rear side, facilitating easy manufacturing of the advantageous devices disclosed herein. The aperture of the optical splitting device may be positioned centrally or substantially centrally (e.g. closer to the centre than the edge) on the reflective surface. The centre of the reflective surface may coincide with the aperture. Thus, when prisms are used, the splitting device may allow half of the light through a slit between the prisms and into the cell, whilst diverting the other half of the light away from the cell. The aperture of the optical splitting device is preferably circular. Circular apertures allow the subsequent laser pulses to exhibit a high degree of spatial coherence. The aperture of the optical splitting device is preferably aligned with an aperture of the multipass cell (e.g. the aperture for allowing light into the cell).

Hence, in generalised terms, the optical arrangement is preferably configured to direct a single laser pulse towards the aperture of the optical splitting device such that a portion of the single laser pulse passes through the aperture of the optical splitting device and into the multipass cell, thereby generating the second laser pulse, and a portion of the single laser pulse is reflected by the reflective surface of the optical splitting device, thereby generating the first laser pulse. This allows a high proportion of the energy of the light to be conserved, as minimal energy is lost when light reflects from a reflective surface or when light passes through an aperture. Thus, such an arrangement is highly efficient. Moreover, two pulses are generated and a temporal delay between the pulses can readily be applied (which may be adjustable) to the pulse that enters the cell. The optical arrangement may be configured to direct the single laser pulse towards the edge of the aperture such that half of the light passes therethrough.

The optical arrangements of the disclosure may comprise: an optical splitting device for generating the first and second laser pulses by splitting a single laser pulse; and/or one or a plurality of unpolarising beamsplitters for generating the first and second laser pulses; and/or one or a plurality of polarising beamsplitters for generating the first and second laser pulses.

As noted previously, the angle at which light enters the multipass cells of this disclosure can be used to control the number of times light traverses the reflector arrangements of the cell and hence the optical path length. Thus, in the described embodiments, the light source may be capable of changing the direction at which light enters the cell (e.g. by being rotatable or by being rotatably mounted). Alternatively, further optical elements (e.g. adjustable mirrors) may be provided to allow the angle of light entering the cell to be varied. The optical arrangement may be configured to guide the first and second laser pulses to the sample along collinear paths. The detector can be any type of detector, including a spectrograph, a photodiode, a charge-coupled device (CCD), a complementary metal-oxide-semiconductor (CMOS) camera, an intensified charge-coupled device (ICCD), an electron multiplying CCD, or one or more microchannel plate detectors. The detector preferably allows detection of light as a function of its wavelengths.

Hence, in generalised terms, the systems of the present disclosure may also comprise: any of the multipass cells described previously; wherein the optical arrangement is configured such that the angle at which light is directed into the multipass cell is adjustable. The angle may be defined relative to an axis defined by the multipass cell (e.g. a longitudinal axis, such as the axis extending between the centres/midpoints of the first and second reflector arrangements). The angle between the direction in which light is directed into the multipass cell and the longitudinal axis defined by the multipass cell may be: from 0° to 20°; from 1° to 15°; or from 2° to 10°. If an aperture of the cell are perpendicular to the axis defined by the cell, then the angle at which light enters the cell may instead be expressed as relative to the normal to the aperture, because in such a case the normal to the aperture would be parallel to the longitudinal axis of the cell.

The provision of an adjustable angle allows the optical path length to be controlled whilst retaining a stable configuration and the advantages associated with such stability. Such optical arrangements can be provided independently of a detector or a light source. In other words, the optical arrangements and the multipass cells of the disclosure can be provided together, for use with any detector and/or light source. The optical elements may be affixed to the multipass cell (e.g. attached to the outside of the cell) or formed integrally with the cell housing.

As noted previously, various light sources can be used with the optical systems disclosed herein. In generalised terms, the present disclosure provides an optical system for generating first and second light components from spatially coherent light (e.g. from light from a coherent light source), comprising a multipass cell arranged to delay the second light component with respect to the first light component, wherein the multipass cell comprises first and second reflector arrangements defining an optical cavity in which the delayed second light component is reflected back and forth multiple times between the first and second reflector arrangements to provide a temporal delay between the first and second light components of 1 ns or greater. The multipass cell can be any of the cells described herein. The first and second light components can be generated using any of the beamsplitting techniques described herein, and the first and second light components may be, for example, pulses of light. Examples of coherent light sources suitable for use with such optical systems include lasers, or partially coherent light sources such as LED light or certain X-ray beams. In some cases, it is also possible to create coherent light by passing light (e.g. monochromatic light from an emission line of a mercury-vapour lamp) through a pinhole spatial filter.

The present disclosure also provides methods for manufacturing the systems, devices, multipass cells and optical arrangements described herein. For instance, a method for manufacturing a multipass cell may comprise providing: a first reflector arrangement; and a second reflector arrangement; wherein the first reflector arrangement is configured such that light incident on the first reflector arrangement is at least partially retroreflected towards the second reflector arrangement. The method of manufacture may further comprise providing any of the features of the multipass cell (e.g. any structural features) described herein. Methods for manufacturing the systems and devices may comprise providing any structural features described herein.

The principle of splitting a beam or pulse of light using an aperture is advantageous independently of its use in the double-pulse systems described herein. Such systems do not cause significant absorption of the energy of the light to be split, as noted previously.

The following numbered clauses provide illustrative examples of optical systems comprising such mechanical beam splitters. The light in the numbered clauses may be continuous light (e.g. a beam) or it may pulsed light (e.g. a laser pulse).

1. An optical system for splitting light into first and second light components, the optical system comprising:
an optical splitting device comprising a reflective surface having an aperture through which light can pass; and
an optical arrangement that is configured to direct light towards the aperture of the optical splitting device such that a portion of the light passes through the aperture, thereby generating the second light component, and a portion of the light is reflected by the reflective surface, thereby generating the first light component.
   2 The optical system of clause 1, wherein the reflective surface is substantially planar.
   3 The optical system of clause 1 or clause 2, wherein the aperture is positioned substantially centrally on the reflective surface.
   4. The optical system of any preceding clause, wherein the aperture is circular.
   5. The optical system of any preceding clause, wherein the optical arrangement comprises one or more reflective surfaces for guiding light towards the optical splitting device.
   6. The optical system of any preceding clause, wherein the optical arrangement comprises one or more focusing elements for focusing light towards the optical splitting device.
   7. The optical system of any preceding clause, wherein the optical arrangement is configured to direct the light towards the edge of the aperture such that half of the light passes therethrough.
   8. The optical system of any preceding clause, wherein the optical arrangement is configured such that the angle at which light is directed towards the aperture is adjustable.
   9. The optical system of any preceding clause, wherein the size of the aperture is adjustable.
   10. The optical system of any preceding clause, further comprising a light source configured to direct light towards the optical arrangement.
   11. The optical system of clause 10, wherein the light source is a laser.
   12. The optical system of clause 11, wherein the laser is a pulsed laser.

The optical system for splitting light into first and second light components may be as described in, for example, FIGS. 11A to 11D, FIGS. 12A and 12B and FIG. 13.

It will be appreciated that many variations may be made to the above apparatus and methods whilst retaining the advantages noted previously. For example, whilst the above embodiments have been described mainly with reference to planar reflective surfaces in the context of providing retroreflective or partially retroreflective surfaces, it will be understood that any material exhibiting retroreflectivity may be used. Moreover, any reflecting surface in this disclosure may be fully reflective or partially reflective.

The disclosure has been described with reference to generic lasers and it will be appreciated that any laser can be used with the systems and cells described herein. For instance, whilst a tuneable diode laser is preferred, any solid-state, gas, liquid, chemical, metal-vapour, dye or semiconductor laser may be used. Other preferred examples include Nd:YAG lasers, CO2 lasers, Excimer lasers and Ruby lasers.

It will also be understood that although the disclosure has been described with reference to particular types of devices and applications, and whilst the disclosure provides particular advantages in such cases, as discussed herein the disclosure may be applied to other types of devices and applications. For instance, the multipass cells of this disclosure may be employed in any scenario in which precise control over the optical path length of light is required.

Each feature disclosed in this specification, unless stated otherwise, may be replaced by alternative features serving the same, equivalent or similar purpose. Thus, unless stated otherwise, each feature disclosed is one example only of a generic series of equivalent or similar features.

As used herein, including in the claims, unless the context indicates otherwise, singular forms of the terms herein are to be construed as including the plural form and, where the context allows, vice versa. For instance, unless the context indicates otherwise, a singular reference herein including in the claims, such as “a” or “an” (such as a laser pulse or a reflector) means “one or more” (for instance, one or more laser pulses, or one or more reflectors). Throughout the description and claims of this disclosure, the words “comprise”, “including”, “having” and “contain” and variations of the words, for example “comprising” and “comprises” or similar, mean “including but not limited to”, and are not intended to (and do not) exclude other components.

The use of any and all examples, or exemplary language (“for instance”, “such as”, “for example” and like language) provided herein, is intended merely to better illustrate the disclosure and does not indicate a limitation on the scope of the disclosure unless otherwise claimed. No language in the specification should be construed as indicating any non-claimed element as essential to the practice of the disclosure.

Any steps described in this specification may be performed in any order or simultaneously unless stated or the context requires otherwise. Moreover, where a step is described as being performed after a step, this does not preclude intervening steps being performed. For instance, if a laser pulse is described as being reflected from a first surface to a second surface, this does not preclude the laser pulse being reflected by additional surfaces before reaching the second surface.

All of the aspects and/or features disclosed in this specification may be combined in any combination, except combinations where at least some of such features and/or steps are mutually exclusive. In particular, the preferred features of the disclosure are applicable to all aspects and embodiments of the disclosure and may be used in any combination. Likewise, features described in non-essential combinations may be used separately (not in combination).

1. A double-pulse laser system for generating first and second laser pulses, comprising a multipass cell arranged to delay the second laser pulse with respect to the first laser pulse.

2. The double-pulse laser system of claim 1, further comprising an optical arrangement configured to direct the second laser pulse into the multipass cell.

3. The double-pulse laser system of claim 2, wherein the optical arrangement is configured to generate the first and second laser pulses from a single laser pulse.

4. The double-pulse laser system of claim 2, wherein the optical arrangement comprises an optical splitting device for generating the first and second laser pulses by splitting a single laser pulse.

5. The double-pulse laser system of claim 4, wherein the optical splitting device is attached to or integral with the multipass cell.

6. The double-pulse laser system of claim 4, wherein the optical splitting device is on an exterior surface of the multipass cell.

7. The double-pulse laser system of claim 4, wherein the multipass cell comprises first and second reflector arrangements defining an optical cavity, and the optical splitting device is on an exterior surface of one of the first and second reflector arrangements.

8. The double-pulse laser system of claim 4, wherein the optical splitting device comprises a reflective surface having an aperture through which at least a portion of a laser pulse can pass.

9. The double-pulse laser system of claim 8, wherein the aperture of the optical splitting device is circular.

10. The double-pulse laser system of claim 8, wherein the aperture of the optical splitting device is aligned with an aperture of the multipass cell for allowing light to enter and/or exit the multipass cell.

11. The double-pulse laser system of claim 8, wherein the optical arrangement is configured to direct a single laser pulse towards the aperture of the optical splitting device such that a portion of the single laser pulse passes through the aperture of the optical splitting device and into the multipass cell, thereby generating the second laser pulse, and a portion of the single laser pulse is reflected by the reflective surface of the optical splitting device, thereby generating the first laser pulse.

12. The double-pulse laser system of claim 3, wherein the optical arrangement comprises: one or a plurality of unpolarising beamsplitters for generating the first and second laser pulses; and/or one or a plurality of polarising beamsplitters for generating the first and second laser pulses.

13. The double-pulse laser system of claim 2, wherein the optical arrangement is configured such that the angle at which the second laser pulse is directed into the multipass cell is adjustable.

14. The double-pulse laser system of claim 2, wherein the multipass cell has a longitudinal axis, wherein the optical arrangement is configured to direct the second laser pulse into the multipass cell at an angle to the longitudinal axis of:
from 0° to 20°;
from 1° to 15°; or
from 2° to 10°.

15. The double-pulse laser system of claim 2, wherein the multipass cell comprises:
a first reflector arrangement; and
a second reflector arrangement.

16. The double-pulse laser system of claim 15, wherein the first reflector arrangement is configured such that light incident on the first reflector arrangement is at least partially retroreflected towards the second reflector arrangement.

17. The double-pulse laser system of claim 16, wherein the first reflector arrangement comprises first and second surfaces that are reflective.

18. The double-pulse laser system of claim 17, wherein the first reflector arrangement is configured such that light incident thereon is reflected from the first surface to the second surface, and to the second reflector arrangement.

19. The double-pulse laser system of claim 17, wherein the first and second surfaces are substantially perpendicular.

20. The double-pulse laser system of claim 17, wherein the first and second surfaces are substantially planar.

21. The double-pulse laser system of claim 20, wherein:
the planes of the first and second surfaces define a common axis; and
the first reflector arrangement is retroreflective for light incident perpendicular to the common axis.

22. The double-pulse laser system of claim 17, wherein the first reflector arrangement comprises first and second prisms and the first and second surfaces are faces of the first and second prisms respectively, preferably wherein the cross-sections of the prisms are right-angled isosceles triangles.

23. The double-pulse laser system of claim 22, wherein the first reflector arrangement comprises a mounting structure configured to mount the first and second prisms such that the first and second surfaces are substantially perpendicular.

24. The double-pulse laser system of claim 17, wherein the first reflector arrangement comprises a third surface that is reflective, wherein the first, second and third surfaces are substantially mutually perpendicular.

25. The double-pulse laser system of claim 15, wherein the second reflector arrangement is configured such that light incident thereon is reflected towards the first reflector arrangement.

26. The double-pulse laser system of claim 15, wherein the second reflector arrangement is configured such that light incident thereon is focused towards the first reflector arrangement.

27. The double-pulse laser system of claim 15, wherein the second reflector arrangement comprises a concave surface that is reflective.

28. The double-pulse laser system of claim 27, wherein the concave surface is an ellipsoidal surface, a spheroidal surface, or a spherical surface.

29. The double-pulse laser system of claim 15, wherein the first and second reflector arrangements define an optical cavity, wherein at least one of the first and second reflector arrangements comprises an aperture for allowing light to enter and/or exit the optical cavity.

30. The double-pulse laser system of claim 29, wherein the size of the aperture of the first and/or second reflector arrangement is adjustable.

31. The double-pulse laser system of claim 29, wherein the first reflector arrangement comprises first and second prisms and a slit between the edges of the first and second prisms defines an aperture of the first reflector arrangement.

32. The double-pulse laser system of 29, wherein the first reflector arrangement comprises first, second and third surfaces and an opening at a corner of the first, second and third surfaces defines an aperture of the first reflector arrangement.

33. The double-pulse laser system of claim 29, wherein an opening at the centre of the second reflector arrangement defines an aperture of the second reflector arrangement.

34. The double-pulse laser system of claim 15, wherein the separation between the first and second reflector arrangements is adjustable.

35. The double-pulse laser system of claim 15, wherein the multipass cell is configured such that the optical path length traversed by light is adjustable.

36. A double-pulse laser-induced breakdown spectrometer for analysing a sample by causing first and second laser pulses to impact the sample, the spectrometer comprising the double-pulse laser system of claim 1 for generating the first and second laser pulses.

37. The double-pulse laser-induced breakdown spectrometer of claim 36, comprising one or more optical elements for guiding the first and second laser pulses to the sample.

38. The double-pulse laser-induced breakdown spectrometer of claim 37, wherein the one or more optical elements are configured to guide the first and second laser pulses to the sample along collinear paths.

39. The double-pulse laser-induced breakdown spectrometer of claim 36, further comprising a detector for detecting light emitted by the sample.
